(19) United States
(12) Patent Application Publication
(10) Pub. No.: US 2005/0247981 A1
(43) Pub. Date: Nov. 10, 2005

(54) Memory device having shielded access lines

(75) Inventor: Ping-Wei Wang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/007,375

(22) Filed: Dec. 8, 2004

Related U.S. Application Data
(60) Provisional application No. 60/569,658, filed on May 10, 2004.
(60) Provisional application No. 60/581,940, filed on Jun. 22, 2004.

(51) Int. Cl. H01L 29/772; H01L 21/4763

(52) U.S. Cl. 257/369; 257/390; 438/618; 438/197

(57) ABSTRACT

An apparatus including, in one embodiment, a plurality of transistors each formed by: (1) at least a portion of one of a plurality of doped regions formed in a substrate; and (2) at least a portion of one of a plurality of first conductors each extending over one of the plurality of doped regions, the plurality of first conductors included in a first metal layer. A second metal layer includes a plurality of second conductors each interconnecting ones of the plurality of transistors. A third metal layer includes a plurality of bit lines each interconnecting ones of the plurality of transistors. A fourth metal layer includes a plurality of word lines each interconnecting ones of the plurality of transistors.

### CROSS-REFERENCE

This application is related to, and claims the benefit of the filing date of, U.S. Provisional Patent Application No. 60/569,658, filed May 10, 2004, Attorney Docket No. 24061.154, entitled “MEMORY DEVICE HAVING SHIELDED ACCESS LINES,” having Ping-Wei Wang named as inventor, the entire disclosure of which is hereby incorporated herein by reference.

This application is also related to, and claims the benefit of the filing date of, U.S. Provisional Patent Application No. 60/581,940, filed Jun. 22, 2004, Attorney Docket No. 24061.538, entitled “MEMORY DEVICE HAVING SHIELDED ACCESS LINES,” having Ping-Wei Wang named as inventor, the entire disclosure of which is hereby incorporated herein by reference.

This application is also related to U.S. Provisional Patent Application No. 60/527,857, filed Dec. 8, 2003, Attorney Docket No. 24061.153, entitled “INTEGRATED CIRCUIT DEVICE WITH CROSSED POWER STRAP LAYOUT,” having Jhon Jhy Liaw named as inventor, the entire disclosure of which is hereby incorporated herein by reference.

This application is also related to the following commonly-assigned U.S. patent applications, the entire disclosure of which is hereby incorporated herein by reference:
“MEMORY CELL HAVING CONDUCTIVE SILL,” Ser. No. 10/819,004, Attorney Docket No. 24061.40, filed Apr. 6, 2004, having Jhon Jhy Liaw named as inventor.
“SRAM DEVICE HAVING HIGH ASPECT RATIO CELL BOUNDARY,” Ser. No. 10/818,133, Attorney Docket No. 24061.171, filed Apr. 5, 2004, having Jhon Jhy Liaw named as inventor.

### BACKGROUND

The physical dimension of a feature on a chip is referred to as “feature size.” Reducing the feature size on a chip permits more components to be fabricated on each chip, and more components to be fabricated on each silicon wafer, thereby reducing manufacturing costs on a per-wafer or per-chip basis. Increasing the number of components in each chip can also improve chip performance because more components may become available to satisfy functional requirements.

An SRAM device is one type of device that may undergo such scaling to reduce manufacturing costs. SRAM is random access memory that retains data bits in its memory as long as power is being supplied. Unlike dynamic random access memory (DRAM), SRAM does not have to be periodically refreshed. SRAM also provides faster access to data than DRAM. Thus, for example, SRAM is frequently employed in a computer's cache memory, or as part of the random access memory digital-to-analog converters in video cards.

However, SRAM is more expensive than other types of memory. Thus, SRAM designers and manufacturers continually strive to reduce the costs of manufacturing SRAM devices. The scaling of features sizes discussed above is one of the means to achieve such cost reduction. However, scaling feature sizes is not the only means available to reduce SRAM manufacturing costs. For example, modifying the layout of features within an SRAM chip to further increase the packing density of SRAM cells within each chip can also reduce manufacturing costs.

### BRIEF DESCRIPTION OF THE DRAWINGS

Aspects of the present disclosure are best understood from the following detailed description when read with the accompanying figures. It is emphasized that, in accordance with the standard practice in the industry, various features may not be drawn to scale. In fact, the dimensions of the various features may be arbitrarily increased or reduced for clarity of discussion.

FIG. 1 is a layout view of at least a portion of one embodiment of an apparatus in an intermediate stage of manufacture according to aspects of the present disclosure.

FIG. 2 is a layout view of the apparatus shown in FIG. 1 in a subsequent stage of manufacture.

FIG. 3 is a layout view of the apparatus shown in FIG. 2 in a subsequent stage of manufacture.

FIG. 4 is a layout view of the apparatus shown in FIG. 3 in a subsequent stage of manufacture.

FIG. 5 is a circuit diagram of at least a portion of one embodiment of an apparatus according to aspects of the present disclosure.

FIG. 6 is a schematic view of at least a portion of one embodiment of an apparatus according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

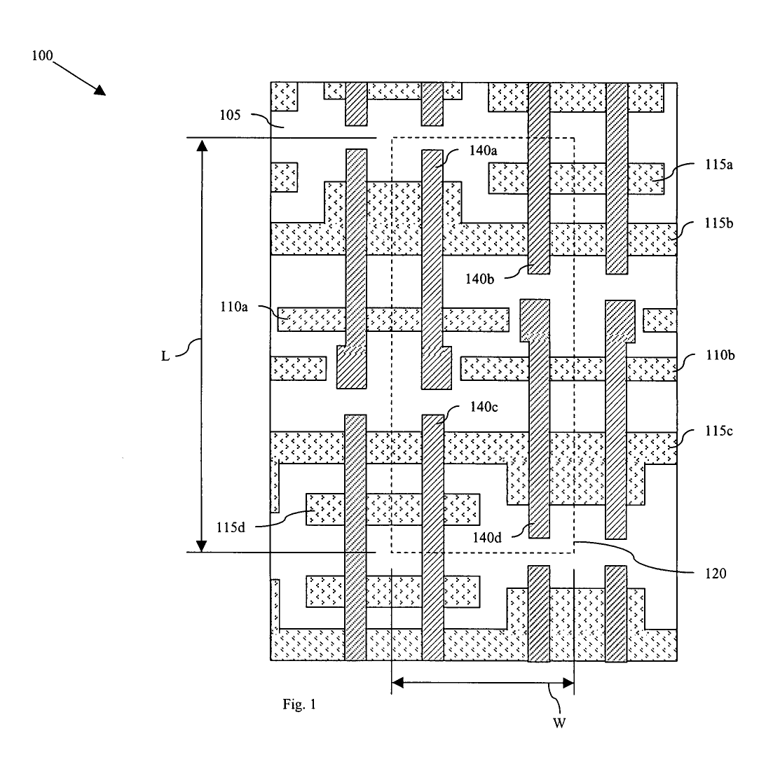

Referring to FIG. 1, illustrated is a layout view of at least a portion of one embodiment of an apparatus 100 according to aspects of the present disclosure. The apparatus 100 may be an SRAM cell or device. However, aspects of the present disclosure are also applicable and/or readily adaptable to other devices or cells, including other memory cells. Moreover, although aspects of the present disclosure may be described herein with reference to a dual-port, eight-transistor memory cell, they are also applicable and/or readily adaptable to single port cells, cells having six transistors or some other number of transistors, and memory for radio frequency applications, among others.

The apparatus 100 includes a substrate 105, n-doped regions 110a and 110b, and p-doped regions 115a-d. The apparatus 100 may comprise one or SRAM unit cells, one of which is indicated in FIG. 1 by reference numeral 120. Each of the SRAM unit cells 120 may include gate electrodes 140a-d.

The substrate 105 may comprise silicon, gallium arsenide, gallium nitride, strained silicon, silicon germanium, silicon carbide, carbide, diamond, and/or other materials. The substrate 105 may also be or comprise a silicon-on-insulator (SOI) substrate, such as a silicon-on-sapphire substrate, a silicon germanium-on-insulator substrate, or another substrate comprising an epitaxial semiconductor layer on an insulator layer. In one embodiment, the substrate 105 may include an air gap to provide insulation of microelectronic devices formed thereon. For example, a silicon-on-nothing (SON) structure may be employed, such that the substrate 105 may include a thin insulation layer or gap comprising air and/or another insulator. In one such embodiment, the substrate 105 includes a silicon cap layer over or on a silicon germanium layer, wherein the silicon germanium layer is substantially or partially removed to form an air gap or void, thereby leaving the silicon cap layer as an insulated device active region for subsequently formed microelectronic devices.

The n-doped regions 110a and 110b may be formed by a high energy implant into the substrate 105, possibly through a patterned photoresist layer. N-type dopant impurities employed to form the n-doped regions 110a and 110b may comprise phosphorus, arsenic, P31, stibium, and/or other materials. Subsequent diffusion, annealing, and/or electrical activation processes may also be employed after the impurity is implanted. The p-doped regions 115a-d may be similarly formed, although possibly with an energy level decreased, for example, in proportion to the atomic masses of the n-type and p-type dopants. P-type dopant impurities may comprise boron, boron fluoride, indium, and/or other materials. As with the formation of the n-doped regions 110a and 110b, formation of the p-doped regions 115a-d may include one or more diffusion, annealing, and/or electrical activation processes.

Moreover, doping schemes other than that shown in the exemplary embodiment of FIG. 1 may be employed within the scope of the present disclosure. For example, the n-doped regions 110a and 110b may be or comprise a p-doped well and the p-doped regions 115a-d may each be or comprise an n-doped well. Similarly, the doped regions 110a, 110b, and 115a-d may be doped with similar dopant types, although possibly to varying degrees of impurity concentration. Although not illustrated, the doped regions 110a, 110b, and/or 115a-d may also collectively be enclosed in a deep n-doped or p-doped well. One or more of the doped regions 110a, 110b, and 115a-d may also comprise more than one doped region.

In one embodiment, the doped regions 110a, 110b, and 115a-d employ boron as a p-type dopant and deuterium-boron complexes as an n-type dopant. The deuterium-boron complexes may be formed by plasma treatment of boron-doped diamond layers with a deuterium plasma. Alternatively, deuterium may be replaced with tritium, hydrogen, and/or other hydrogen-containing gases. The impurity concentration of the doped regions may be controlled by a direct current or a radio frequency bias of the substrate 105. The above-described processes may also be employed to form lightly-doped source/drain regions in the substrate 105.

The gate electrodes 140a-d may comprise one or more patterned and/or selectively deposited layers of polysilicon, W, Ti, Ta, TiN, TaN, Hf, Mo, metal silicide, SiO₂, nitrided SiO₂, SiOₓN_{y}, WSiₓ, V, Nb, MoSiₓ, Cu, Al, carbon nanotubes, high-k dielectrics, alloys thereof, and/or other materials. Manufacturing processes which may be employed to form the gate electrodes 140a-d include imprint lithography, immersion photolithography, mask-less photolithography, chemical-vapor deposition (CVD), plasma-enhanced CVD (PECVD), atmospheric pressure CVD (APCVD), physical-vapor deposition (PVD), atomic layer deposition (ALD), and/or other processes. The process environment during such processing may include hydrogen (H₂) and carbon gas reactants, which may be excited by a plasma. The process gas/environment may also or alternatively include, CH₄, C₂H₆, C₃H₈, and/or other carbon containing sources.

The gate electrodes 140a-d may also include a seed layer comprising Ni, Cr, Nb, V, W, and/or other materials, possibly formed by PVD, ALD, PECVD, APCVD, LPCVD, and/or other processing techniques. The gate electrodes 140a-d may also include or be formed on or over one or more gate dielectric layers. Such gate dielectric layers may comprise SiO₂, SiON, HfO, Ta₂O₅, Al₂O₃, nitrided oxide, CVD oxide, thermal oxide, a nitrogen-containing dielectric material, a high-k dielectric material, and/or other materials, and may be formed by CVD, LPCVD, PECVD, PVD, ALD, and/or other processes.

As shown in FIG. 1, the gate electrode 140a may extend over the doped regions 110a and 115b, the gate electrode 140b may extend over the doped regions 115a and 115b, the gate electrode 140c may extend over the doped regions 115c and 115d, and the gate electrode 140d may extend over the doped regions 110b and 115c. Thus, one or more of the gate electrodes 140a-d may be shared gate electrodes, extending over more than one of the doped regions 110a, 110b, and/or 115a-d, such as for supporting more than one transistor device. The gate electrodes 140a-d, whether or not they are configured as shared gate electrodes, may also extend beyond the boundary of a particular unit cell 120. Moreover, as in the illustrated embodiment, the gate electrodes 140a-d may also include wider portions, such as where subsequently formed contacts or vias may land. Two or more of the gate electrodes 140a-d may also have substantially similar footprint shapes and areas. For example, in the illustrated embodiment, the gate electrodes 140a and 140d have substantially similar footprint shapes and areas.

The unit cell boundary for each SRAM unit cell 120 (such as indicated by the dashed lines) may have an aspect ratio greater than about 2.0, and in some embodiments may have an aspect ratio grater than about 3.2. The aspect ratio is the ratio of a larger primary dimension (“L” in the illustrated embodiment) of the cell 120 to a smaller primary dimension (“W” in the illustrated embodiment). For example, the SRAM unit cell 120 may have a length L ranging between about 0.32 μm and about 12 μm and a width W ranging between about 0.08 μm and about 2 μm, or an aspect ratio ranging between about 4 and about 6. In another embodiment, the SRAM unit cell 120 may have a length L ranging between about 12 nm and about 120 nm and a width W ranging between about 4 nm and about 20 nm. The aspect ratio of the cells 120 may also range between about 3 and about 6, and may vary from cell to cell. In another embodiment, the aspect ratio of one, several, or all of the cells 120 is greater than about 3.5.

The unit cell boundary of each cell 120 may also have a width (W) about equal to 5 times a design constant. The design constant may be a minimum width of one or more of the gate electrodes 140a-d. Such a minimum width may be the minimum width of one of the gate electrodes 140a-d relative to the remaining gate electrodes 140a-d, or may be a minimum width of a gate electrode 140a-d relative to wider portions of that particular gate electrode. Such a minimum width of a gate electrode 140a-d may also be the minimum gate width that is able to be manufactured. In one embodiment, the minimum width is about 0.20 μm. Moreover, the minimum spacing between features may be about 0.20 μm, or otherwise substantially similar or equal to the minimum width of one or more of the gate electrodes 140a-d. Subsequently formed features may have similar minimum widths and/or spacing.

Two or more of the gate electrodes 140a-d and/or doped regions 110a, 110b, and 115a-d and/or other features may also be oriented substantially symmetrical within a cell 120. For example, within the cell 120 illustrated in FIG. 1, the gate electrodes 140a and 140d are oriented substantially symmetrically, the gate electrodes 140b and 140c are oriented substantially symmetrically, the doped regions 110a and 110b are oriented substantially symmetrically, the doped regions 115a and 115d are oriented substantially symmetrically, and the doped regions 115b and 115c are oriented substantially symmetrically. Moreover, one or more pairs of neighboring cells 120 may be mirror images of each other.

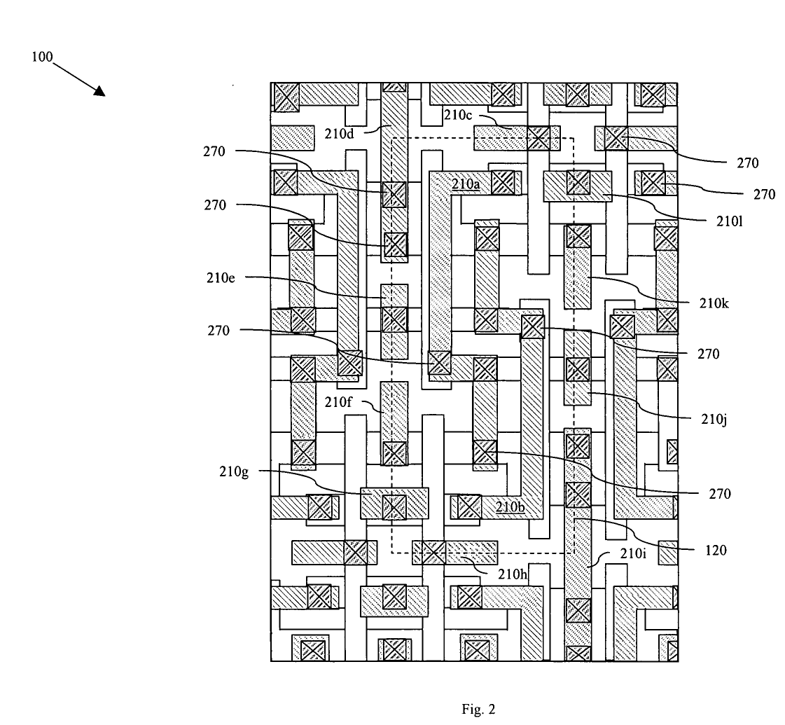

Referring to FIG. 2, illustrated is a layout view of the apparatus 100 shown in FIG. 1 in a subsequent stage of manufacture according to aspects of the present disclosure, wherein a metal layer has been formed over various previously formed features. The metal layer may include one or more layers comprising aluminum, gold, copper, silver, tungsten, titanium, titanium nitride, tantalum, tantalum nitride, alloys thereof, and/or other materials. Although not limited within the scope of the present disclosure, the metal layer may be formed by imprint lithography, immersion photolithography, mask-less photolithography, CVD, PECVD, PVD, ECP, ALD, and/or other processes. The metal layer may also be formed by selective deposition or blanket deposition followed by a patterning process. In one embodiment, the metal layer is formed by one or more of the processes described above regarding the formation of the gate electrodes 140a-d, and/or comprises one or more of the materials described above regarding possible compositions of the gate electrodes 140a-d.

The metal layer may include conductors 210a-1. One or more of the conductors, such as the conductors 210a and 210b, may have a number of turns, as opposed to substantially straight or rectangular ones of the conductors 210a-1, such as the conductors 210c and 210d. For example, the conductor 210a includes four turns or bends in the illustrated embodiment. Consequently, the ones of the conductors 210a-1 that have at least one turn may interconnect two or more misaligned, underlying features. Two or more of the conductors 210a-1, or other features defined from the metal layer, may also have substantially similar footprints, shapes and/or areas. For example, in the illustrated embodiment, the conductors 210a-1 have substantially similar footprint, shapes and areas. The features defined from the metal layer may also have a minimum width about equal to a design rule for the apparatus 100.

Two or more of the conductors 210a-1 and/or other features formed from the metal layer may also be oriented substantially symmetrical within a cell 120. For example, within the cell 120 illustrated in FIG. 2, the conductors 210a and 210b are oriented substantially symmetrically, the conductors 210c and 210h are oriented substantially symmetrically, the conductors 210d and 210i are oriented substantially symmetrically, the conductors 210e and 210j are oriented substantially symmetrically, the conductors 210f and 210k are oriented substantially symmetrically, and the conductors 210g and 2101 are oriented substantially symmetrically.

The apparatus 100 also includes contacts or vias (hereafter collectively referred to as contacts) 270 extending between various components of the metal layer shown in FIG. 2 and underlying features. Although illustrated as overlying the conductors 210a-1 in FIG. 2, it is understood that the contacts 270 may lie under the conductors 210a-1 (i.e., between the conductors 210a-1 and the substrate 105). This convention will be employed hereafter. That is, although contacts (including contacts 270 and others) may be illustrated as overlying conductive features to which the contacts are connected in the figures herein, it is understood that one or more of such contacts may extend away from the contacted, conductive features towards the substrate 105 (although such contacts may not contact the substrate 105).

The contacts 270 may be formed by processes similar to those employed to form the metal layer, and may be formed prior to formation of the metal layer. However, in one embodiment, one or more of the contacts 270 may be formed by a damascene or dual-damascene process as part of the processes employed to form the metal layer. Many of the contacts 270 may land on underlying features to delineate a number of transistors included in the apparatus 100. In the illustrated embodiment, the apparatus 100 includes four pass-gate transistors (PG-A, PG-A-bar, PG-B, PG-B-bar), two pull-down transistors (PD-1 and PD-2), and two pull-up transistors (PU-1 and PU-2). Table 1 lists the interconnections made by the contacts 270 to corresponding transistor nodes according the embodiment shown in FIG. 2. Each row in Table 1 indicates the existence of a contact 270 or other interconnection feature.

TABLE 1

| Metal Layer | Underlying | |
|---|---|---|
| Component | Component | for Transistor Node |
| 210a | 115a | PG-B-bar source |
| 210a | 140a | PU-2 gate / PD-2 gate |
| 210a | 110b | PU-1 drain |
| 210a | 115c | PD-1 source / PG-A source |
| 210b | 115b | PD-2 source / PG-B source |
| 210b | 110a | PU-2 drain |
| 210b | 140d | PU-1 gate / PD-1 gate |
| 210b | 115d | PG-A-bar source |
| 210c | 140b | PG-B gate / PG-B-bar gate |
| 210d | 115b | PD-2 drain |
| 210e | 110a | PU-2 source |
| 210f | 115c | PG-A drain |
| 210g | 115d | PG-A-bar drain |
| 210h | 140c | PG-A-bar gate / PG-A gate |
| 210i | 115c | PD-1 drain |
| 210j | 110b | PU-1 source |
| 210k | 115b | PG-B drain |
| 210l | 115a | PG-B-bar drain |

Of course, other features or components may interpose the metal layer and the underlying features for interconnection thereof, either in addition to or in the alternative to one or more of the contacts 270. Interconnection schemes other than that described in Table 1 are also within the scope of the present disclosure. The apparatus 100 may also include more or fewer transistors and/or contacts 270 than in the illustrated embodiment.

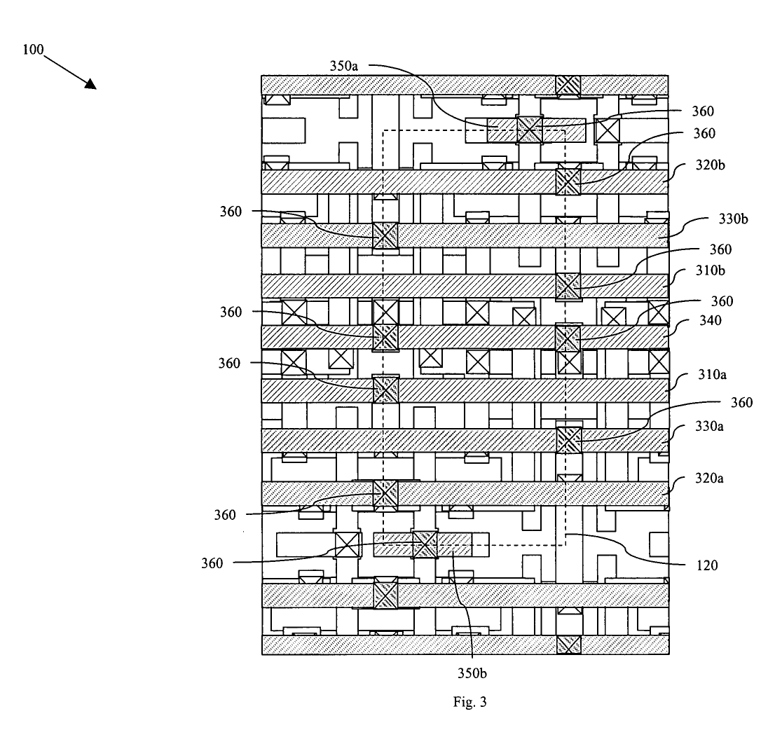

Referring to FIG. 3, illustrated is a layout view of the apparatus 100 shown in FIG. 2 in a subsequent stage of manufacture according aspects of the present disclosure, in which a second metal layer is formed over the previously formed metal layer. In one embodiment, the second metal layer is substantially similar in composition and manufacture to the previously formed metal layer described above.

The second metal layer may include a bit line (BL-A) 310a, a bit line (BL-B) 310b, a bit-bar line (BL-A-bar) 320a, and a bit-bar line (BL-B-bar) 320b. The second metal layer may also include voltage lines, herein referred to as Vss-A 330a, Vss-B 330b, and Vdd 340. The Vss lines 330a and 330b may be common or ground lines. The second metal layer may also include straps 350a, 350b employed for interconnection of one or more components above the second metal layer with one or more components below the second metal layer.

Two or more of the features defined from the second metal layer may have substantially similar footprint shapes and areas. For example, in the illustrated embodiment, each of the bit lines 310a and 310b, the bit-bar lines 320a and 320b, and the voltage lines 330a, 330b, and 340 have substantially rectangular shapes. Consequently, the packing density of such lines may be increased relative to conventional designs. The features defined from the second metal layer may also have a minimum width about equal to a design rule for the apparatus 100, or otherwise as small as the widths of the gate electrodes 140a-d described above. As also shown in FIG. 3, one or more of the bit lines 310a and 310b, and/or the bit-bar lines 320a and 320b, may be substantially parallel to the shorter side or dimension of the unit cell 120.

Two or more of the bit lines 310a and 310b, the bit-bar lines 320a and 320b, and the voltage lines 330a, 330b, and 340, and/or other features formed from the second metal layer, may also be oriented substantially symmetrical within a cell 120. For example, within the cell 120 illustrated in FIG. 3, the bit line 310a and the bit-bar line 320b are oriented substantially symmetrically, the bit line 310b and the bit-bar line 320a are oriented substantially symmetrically, and the voltage lines 330a and 330b are oriented substantially symmetrically.

The apparatus 100 also includes contacts 360 extending between various components of the first and second metal layers. One or more of the contacts 360 (and many other contacts described herein) may be or comprise a landing pad for receiving a subsequently formed contact or via. In one embodiment, the contacts 360 are substantially similar in composition and manufacture to the contacts 270 shown in FIG. 2. Table 2 lists the interconnections made between the first and second metal layers by the contacts 360 according to the embodiment shown in FIG. 3. Each row in Table 2 indicates the existence of a contact 360 or other interconnection feature.

TABLE 2

| | Metal Layer | |
|---|---|---|
| Metal Layer 2 Component | 1 Component | for Transistor Node |
| BL-A (310a) | 210f | PG-A drain |
| BL-B-bar (320b) | 210l | PG-B-bar drain |
| BL-A-bar (320a) | 210g | PG-A-bar drain |
| BL-B (310b) | 210k | PG-B drain |
| Vss-A (330a) | 210d | PD-2 drain |
| Vss-B (330b) | 210i | PD-1 drain |
| Vdd (340) | 210e / 210j | PU-2 source / PU-1 source |
| Pass gate strap (350a) | 210c | PG-B gate / PG-B-bar gate |
| Pass gate strap (350b) | 210h | PG-A-bar gate / PG-A gate |

Of course, other features or components may interpose the first and second metal layers for interconnection thereof, either in addition to or in the alternative to one or more of the contacts 360. Interconnection schemes other than that described in Table 2 are also within the scope of the present disclosure.

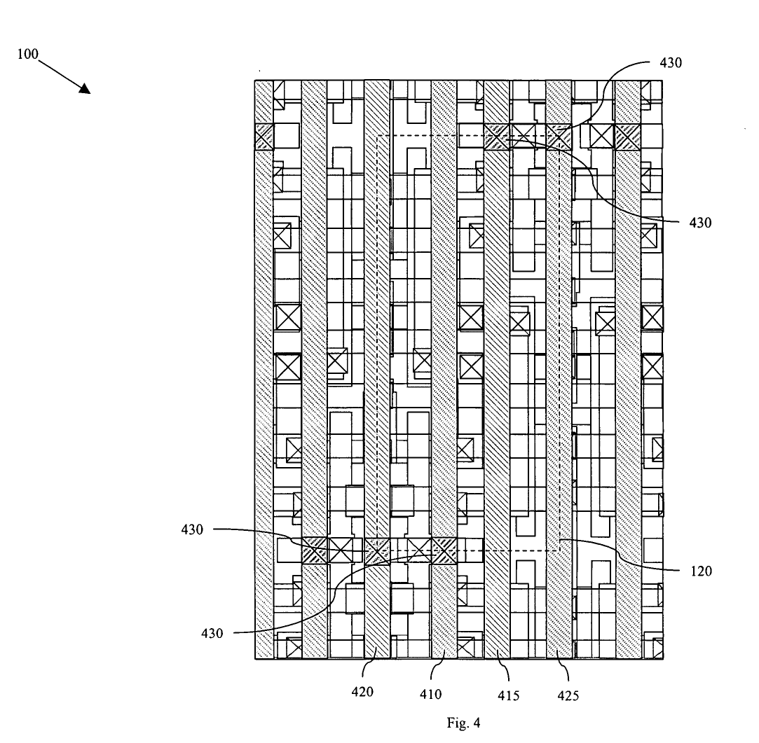

Referring to FIG. 4, illustrated is a layout view of the apparatus 100 shown in FIG. 3 in a subsequent stage of manufacture according aspects of the present disclosure, in which a third metal layer is formed over the second metal layer. In one embodiment, the third metal layer is substantially similar in composition and manufacture to the first metal layer described above. The features defined from the third metal layer may also have a minimum width about equal to a design rule for the apparatus 100, or otherwise as small as the widths of the gate electrodes 140a-d described above.

The third metal layer includes a word line (WL-A) 410, a word line (WL-B) 415, a ground word line (GWL-A) 420, and a ground word line (GWL-B) 425. Two or more of the features defined from the third metal layer may have substantially similar footprints, shapes and/or areas. For example, in the illustrated embodiment, each of the word lines 410 and 415, and each of the ground word lines 420 and 425, have substantially rectangular shapes. Consequently, the packing density of such lines may be increased relative to conventional designs. The features defined from the third metal layer may also have a minimum width about equal to a design rule for the apparatus 100, or otherwise as small as the widths of the gate electrodes 140a-d described above.

Two or more of the word lines 410 and 415 and the ground word lines 420 and 425, and/or other features formed from the second metal layer, may also be oriented substantially symmetrical within a cell 120. For example, within the cell 120 illustrated in FIG. 4, the word lines 410 and 415 are oriented substantially symmetrically, and the ground word lines 420 and 425 are oriented substantially symmetrically.

The apparatus 100 also includes contacts 430 extending between various components of the second and third metal layers. In one embodiment, the contacts 430 are substantially similar in composition and manufacture to the contacts 270 shown in FIG. 2. Table 3 lists the interconnections made between the second and third metal layers by the contacts 430 according to the embodiment shown in FIG. 4. Each row in Table 3 indicates the existence of a contact 430 or other interconnection feature.

TABLE 3

| Metal Layer | | |
|---|---|---|
| 3 Component | Metal Layer 2 Component | for Transistor Node |
| WL-A (410) | 350b | PG-A gate / PG-A-bar gate |
| WL-B (415) | 350a | PG-B gate / PG-B-bar gate |
| GWL-A (420) | 350b | PG-A gate / PG-A-bar gate |
| GWL-B (425) | 350a | PG-B gate / PG-B-bar gate |

Of course, other features or components may interpose the second and third metal layers for interconnection thereof, either in addition to or in the alternative to one or more of the contacts 430. Interconnection schemes other than that described in Table 3 are also within the scope of the present disclosure.

In one embodiment, one or more of the first and/or second metal layers are configured to be shielded by at least one overlying layer, such as the third metal layer or the second metal layer. For example, the third metal layer may shield one or more of the first and/or second metal layers from electromagnetic interference, signal noise, signal interference, and/or ionizing radiation. In one embodiment, the shielding provided by the third metal layer conductors may reduce soft-error in the apparatus 100 by at least about 25%. In another embodiment, the shielding provided by the second metal layer conductors may also reduce soft-error rate in the memory device by at least about 25%. Moreover, since shielding layers may be formed by the third or second metal layers, the subsequently formed circuit layout may initiate as low as the fourth metal layer. This may save one or two metal layers for circuit design, such as in embodiments in which the circuit layout begins at a sixth metal layer.

According to at least one embodiment of the present disclosure, employing the second metal layer to form several or all bit lines and/or other components for a given cell 120 can improve speed and decrease the cost, complexity, and/or size or resulting devices and products employing such devices. Moreover, at least partially because the bit lines and/or other components may not be formed by or from the third metal layer, the word line or other components of the third metal layer may provide shielding for the bit lines.

In addition, some aspects of the present disclosure may allow greater symmetry, such as symmetry for dual port devices, possibly providing symmetry of one or more or all lower layers therein. Consequently, coupling resistance and/or capacitance may be symmetric or more symmetric for bit and bit-bar lines.

Some aspects of the present disclosure may also allow bit and bit-bar lines to be shielded, such as from word and ground lines. Also, noise and coupling of/to bit and bit-bar lines, and/or other signal lines, may be reduced or avoided by aspects of the present disclosure.

After the features shown in FIG. 4 have been formed, the apparatus 100 may be completed by conventional and/or future-developed processes. For example, additional metal layers may be formed over the third metal layer shown in FIG. 4, such as for the further interconnection of the apparatus 100 with other devices or components, including other neighboring and/or remote apparatus, in the chip and/or wafer in which the apparatus 100 is incorporated. In one embodiment, multiple instances of the apparatus 100 may be substantially repeated to form an SRAM memory array and/or other type of memory cell array.

The apparatus 100 described above may also include one or more inter-metal dielectric or other insulating layers interposing the various conductive components. Such insulating layers, each of which may comprise multiple insulating layers, may be planarized to provide a substantially planar surface for subsequent processing. The insulating layers may comprise SiO₂, fluoride-doped glass (FSG), SiLK™ (a product of Dow Chemical of Michigan), Black Diamond® (a product of Applied Materials of Santa Clara, Calif.), low-k dielectrics, and/or other materials, and may be formed by CVD, ALD, PVD, spin-on coating, and/or other processes.

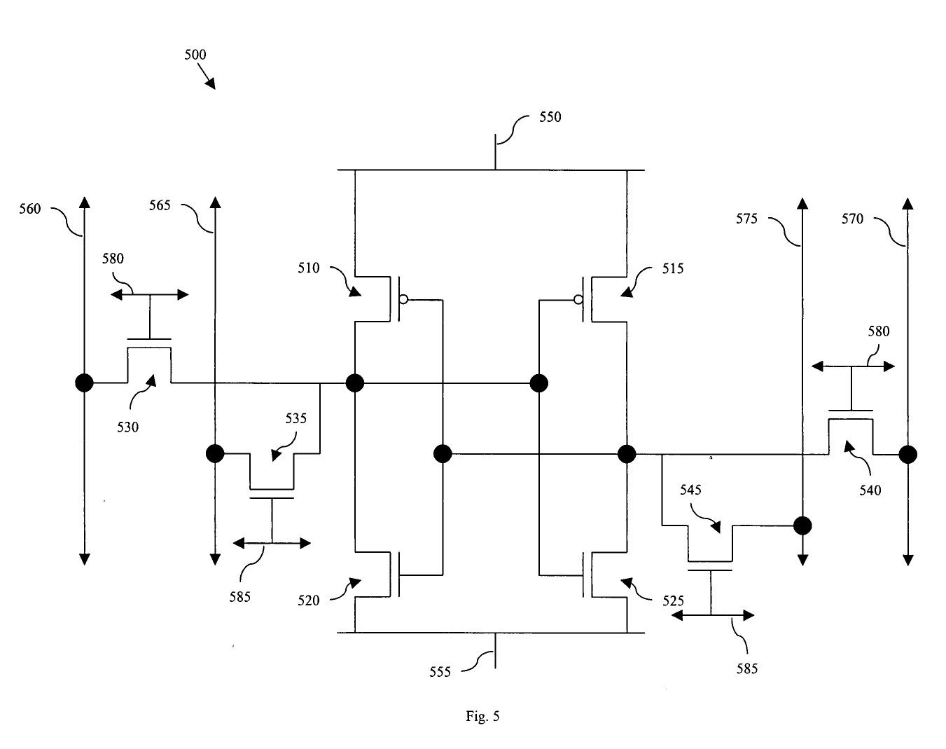

Referring to FIG. 5, illustrated is a circuit diagram of at least a portion of one embodiment of an apparatus 500 according to aspects of the present disclosure. The apparatus 500 may be substantially similar to the apparatus 100 shown in FIG. 4, and/or a more completed version thereof. For example, the apparatus 500 may be, comprise, or form at least a portion of an SRAM cell, device, and/or array. The apparatus 500 includes apull-up transistor (PU-1) 510, a pull-up transistor (PU-2) 515, a pull-down transistor (PD-1) 520, a pull-down transistor (PD-2) 525, a pass-gate transistor PG-A 530, a pass-gate transistor PG-B 535, a pass-gate transistor PG-A-bar 540, and a pass-gate transistor PG-B-bar 545. In one embodiment, the pull-up transistors 510, 515 are PMOS transistors, whereas the pull-down transistors 520, 525 and pass-gate transistors 530, 535, 540, 545 are NMOS transistors, although other configurations of NMOS and PMOS transistors are within the scope of the present disclosure.

The sources of the pull-up transistors 510, 515 are electrically coupled to a power source (referred to herein as Vdd) 550. The drain of the pull-up transistor 510 is electrically coupled to the sources of the pass-gate transistors 530, 535, the source of the pull-down transistor 520, and the gates of the pull-up transistor 515 and the pull-down transistor 525. Similarly, the drain of the pull-up transistor 515 is electrically coupled to the sources of the pass-gate transistors 540, 545, the source of the pull-down transistor 525, and the gates of the pull-up transistor 510 and the pull-down transistor 520. The drains of the pull-down transistors 520, 525 are electrically coupled to a ground, common, or Vss contact (hereafter collectively referred to as a Vss contact) 555.

The drain of the pass-gate transistor 530 is electrically coupled to a bit line (BL-A) 560, and the drain of the pass-gate transistor 535 is electrically coupled to a bit line (BL-B) 565. The drain of the pass-gate transistor 545 is electrically coupled to a bit-bar line (BL-B-bar) 575, and the drain of the pass-gate transistor 540 is electrically coupled to a bit-bar line (BL-A-bar) 570. The gates of the pass-gate transistors 530 and 540 are electrically coupled to a word line 580, and the gates of the pass-gate transistors 535 and 545 are electrically coupled to a word (or word-bar) line 585. The bit and bit-bar lines 560, 565, 570, 575 and the word lines 580, 585 may extend to other SRAM cells and/or other components, including row and column latch, decoder, and select drivers, control and logic circuitry, sense amps, muxes, buffers, etc.

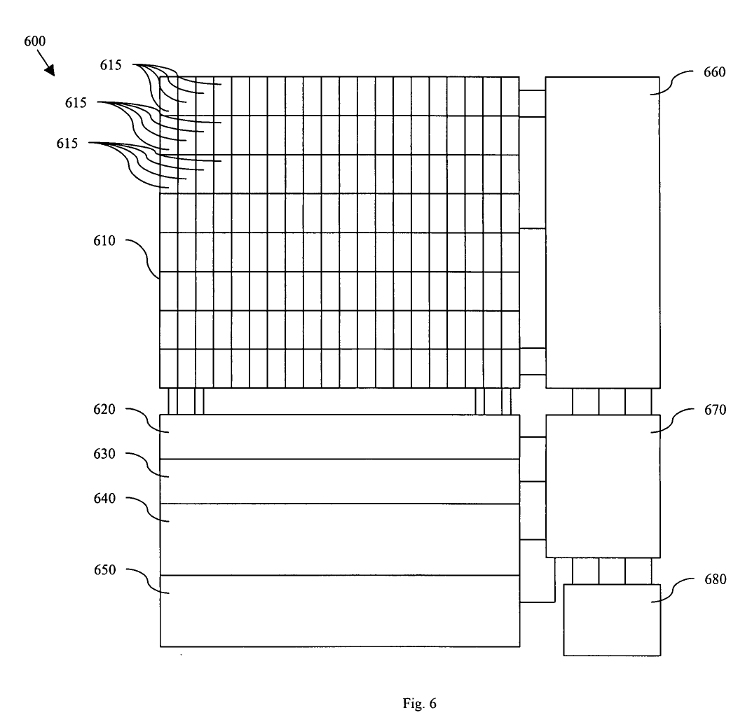

Referring to FIG. 6, illustrated is a schematic view of at least a portion of an embodiment of an apparatus 600 constructed according to aspects of the present disclosure. The apparatus 600 is one environment in which the apparatus 100, 120, and/or 500 described above may be implemented. For example, the apparatus 600 may include an SRAM cell array 610 comprising a plurality of SRAM cells 615, possibly arranged in a series of rows and columns, wherein one or more of the SRAM cells 615 may be substantially similar to the apparatus 100, 120, and/or 500. Components and/or features within each of the SRAM cells 615 may be oriented substantially symmetrically. Also, or alternatively, neighboring ones of the SRAM cells 615 may be mirror images.

In the illustrated embodiment, the apparatus 600 also includes a pre-charge cell array 620, column multiplexers 630, sense amplifiers 640, input/output buffers 650, row address decoders 660, one or more controllers 670, and one or more address inputs 680. The pre-charge cell array 620, the column multiplexers 630, and/or other components may be electrically coupled to the SRAM cell array 610 by a plurality of bit, bit-bar, and/or word lines, including multiple ports of such access lines. Other embodiments of the apparatus 600 may also include more or fewer of such components, and/or alternative components, within the scope of the present disclosure.

Aspects of the present disclosure may allow the formation of a memory device having a short and/or thin bit line design. In some embodiments, decreasing the length of bit lines can increase the sensing and/or operating speed of the device in which the bit lines are incorporated.

Aspects of the present disclosure may also permit bit lines to be oriented substantially parallel to the shorter side or dimension of a unit memory cell. As such, the packing density of cells incorporating such bit lines may be increased in some embodiments.

Aspects of the present disclosure may also permit one, several, or all bit lines to be formed at the second metal layer formed during the fabrication process. As such, in some embodiments, packing density may be increased, and the bit lines may be shielded by overlying lines, including word lines. Moreover, the shielding of the bit lines formed from the second metal layer may comprise constant potential metal layers. Consequently, electrical characteristics of a particular unit memory cell may be substantially symmetric. The bit lines may also be shielded by conductive features on the same metal layer (e.g., the second metal layer). For example, the bit lines may be shielded on two sides (substantially parallel to primary axes of the bit lines) by features formed in the same metal layer.

Substantial symmetry of various features in a memory cell may also be achieved according to aspects of the present disclosure. For example, the features defined from one or more polysilicon or metal layers may be substantially symmetric within the layer(s) and within a unit memory cell. In one embodiment, the features within each of several layers may be substantially symmetric. For example, as in the embodiments described above, the features of one or more of the doped region layer, the gate electrode layer, the contact layer(s), and/or the first, second, and/or third metal layers may be substantially symmetric within each layer and within a unit memory cell.

Thus, the present disclosure introduces an apparatus including, in one embodiment, a plurality of transistors each formed by: (1) at least a portion of one of a plurality of doped regions formed in a substrate; and (2) at least a portion of one of a plurality of first conductors each extending over one of the plurality of doped regions, the plurality of first conductors included in a first metal layer. A second metal layer includes a plurality of second conductors each interconnecting ones of the plurality of transistors. A third metal layer includes a plurality of bit lines each interconnecting ones of the plurality of transistors. A fourth metal layer includes a plurality of word lines each interconnecting ones of the plurality of transistors. In one embodiment, all bit lines are formed in the third metal layer, and/or all word lines are formed in the fourth metal layer. Such an apparatus may be an SRAM cell, such as an eight-transistor SRAM cell, including one of a plurality of SRAM cells in an SRAM array, wherein the SRAM array may be interconnected, at least indirectly, to ones of a plurality of row decoders and/or ones of a plurality of column multiplexers, such as by corresponding ones of the pluralities of bit and word lines.

A method of, for example, manufacturing such an apparatus is also provided in the present disclosure. In one embodiment, such a method includes forming a plurality of doped regions in a substrate and forming a first metal layer including a plurality of first conductors each extending over one of the plurality of doped regions, thereby forming a plurality of transistors each including at least a portion of one of the plurality of doped regions and at least a portion of one of the plurality of first conductors. A second metal layer including a plurality of second conductors each interconnecting ones of the plurality of transistors may then be formed. A third metal layer including a plurality of bit lines each interconnecting ones of the plurality of transistors may then be formed. A fourth metal layer including a plurality of word lines each interconnecting ones of the plurality of transistors may then be formed. Other layers, features, and/or components may then be formed.

The foregoing has outlined features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. An apparatus, comprising:
a plurality of transistors each formed by:
at least a portion of one of a plurality of doped regions formed in a substrate; and
at least a portion of one of a plurality of first conductors each extending over one of the plurality of doped regions, the plurality of first conductors included in a first metal layer;
a second metal layer including a plurality of second conductors each interconnecting ones of the plurality of transistors;
a third metal layer including a plurality of bit lines each interconnecting ones of the plurality of transistors; and
a fourth metal layer including a plurality of word lines each interconnecting ones of the plurality of transistors.

2. The apparatus of claim 1 wherein ones of the plurality of bit lines are configured to shield corresponding ones of the plurality of first conductors and the plurality of second conductors.

3. The apparatus of claim 1 wherein ones of the plurality of transistors form a unit memory cell having a substantially rectangular shape, wherein each of the plurality of bit lines is substantially perpendicular to a long axis of the unit memory cell.

4. The apparatus of claim 1 wherein the plurality of bit lines are each mutually, substantially parallel.

5. The apparatus of claim 1 wherein ones of the plurality of word lines are configured to shield corresponding ones of the plurality of conductors.

6. The apparatus of claim 1 wherein ones of the plurality of word lines are configured to shield corresponding ones of the plurality of bit lines.

7. The apparatus of claim 1 wherein ones of the plurality of transistors form a unit memory cell having a substantially rectangular shape, wherein each of the plurality of word lines is substantially parallel to a long axis of the unit memory cell.

8. The apparatus of claim 7 wherein each of the plurality of bit lines is substantially perpendicular to the long axis of the unit memory cell.

9. The apparatus of claim 1 wherein the plurality of word lines are each mutually, substantially parallel.

10. The apparatus of claim 1 wherein ones of the plurality of transistors form a unit memory cell, and wherein each of the plurality of first conductors and the plurality of second conductors is one of a pair of mirror-image conductors.

11. The apparatus of claim 1 wherein:
ones of the plurality of transistors form a unit memory cell;
each of the plurality of doped regions within the unit memory cell are substantially symmetric;
each of the plurality of first conductors within the unit memory cell are substantially symmetric; and
each of the plurality of second conductors within the unit memory cell are substantially symmetric.

12. The apparatus of claim 11 wherein each of the plurality of bit lines within the unit memory cell are substantially symmetric.

13. The apparatus of claim 12 wherein each of the plurality of word lines within the unit memory cell are substantially symmetric.

14. The apparatus of claim 1 wherein the plurality of transistors includes eight SRAM transistors interconnects to form an SRAM cell.

15. The apparatus of claim 1 wherein the plurality of transistors includes:
first and second pull-up transistors;
first and second pull-down transistors; and
first, second, third, and fourth pass-gate transistors.

16. The apparatus of claim 15 wherein:
sources of the first and second pull-up transistors are electrically coupled at least indirectly to a power source;
a drain of the first pull-up transistor is electrically coupled at least indirectly to sources of the first and second pass-gate transistors, a source of the first pull-down transistor, a gate of the second pull-up transistor, and a gate of the second pull-down transistor;
a drain of the second pull-up transistor is electrically coupled at least indirectly to sources of the third and fourth pass-gate transistors, a source of the second pull-down transistor, a gate of the first pull-up transistor, and a gate of the first pull-down transistor;
drains of the first and second pull-down transistors are electrically coupled at least indirectly to a lower potential than the power source;
a drain of the first pass-gate transistor is electrically coupled at least indirectly to a first one of the plurality of bit lines;
a drain of the second pass-gate transistor is electrically coupled at least indirectly to a second one of the plurality of bit lines;
a drain of the third pass-gate transistor is electrically coupled at least indirectly to a third one of the plurality of bit lines;
a drain of the fourth pass-gate transistor is electrically coupled at least indirectly to a fourth one of the plurality of bit lines;
gates of the first and third pass-gate transistors are electrically coupled at least indirectly to one of the plurality of word lines; and
gates of the second and third pass-gate transistors are electrically coupled at least indirectly to a second one of the plurality of word lines.

17. The apparatus of claim 15 wherein the first and second pull-up transistors are PMOS transistors, and wherein the first and second pull-down transistors and the first, second, third, and fourth pass-gate transistors are NMOS transistors.

18. The apparatus of claim 1 wherein ones of the plurality of transistors form one of a plurality of SRAM cells in an SRAM array, wherein the SRAM array is at least indirectly interconnected to a plurality of column multiplexers and a plurality of row address decoders by corresponding ones of the plurality of bit lines and the plurality of word lines.

19. A method, comprising:
forming a plurality of doped regions in a substrate;
forming a first metal layer including a plurality of first conductors each extending over one of the plurality of doped regions, thereby forming a plurality of transistors each including at least a portion of one of the plurality of doped regions and at least a portion of one of the plurality of first conductors;
forming a second metal layer including a plurality of second conductors each interconnecting ones of the plurality of transistors;
forming a third metal layer including a plurality of bit lines each interconnecting ones of the plurality of transistors; and
forming a fourth metal layer including a plurality of word lines each interconnecting ones of the plurality of transistors.

20. The method of claim 19 wherein:
ones of the plurality of transistors form a unit memory cell;
each of the plurality of doped regions within the unit memory cell are substantially symmetric;
each of the plurality of first conductors within the unit memory cell are substantially symmetric;
each of the plurality of second conductors within the unit memory cell are substantially symmetric;
each of the plurality of bit lines within the unit memory cell are substantially symmetric; and
each of the plurality of word lines within the unit memory cell are substantially symmetric.
